(19) United States
(12) Patent Application Publication
(10) Pub. No.: US 2022/0055955 A1
(43) Pub. Date: Feb. 24, 2022

(54) METHOD OF MAKING A CERAMIC MATRIX COMPOSITE THAT EXHIBITS MOISTURE AND ENVIRONMENTAL RESISTANCE

(71) Applicant: Rolls-Royce High Temperature Composites Inc., Cypress, CA (US)

(72) Inventors: Richard Kidd, Rancho Palos Verdes, CA (US); Sungbo Shim, Irvine, CA (US); Kelly Kranjc, Irvine, CA (US); Robert Shinavski, Mission Viejo, CA (US)

(21) Appl. No.: 16/997,094

(22) Filed: Aug. 19, 2020

(51) Int. Cl. C04B 35/80; C04B 35/628; C04B 35/657; C04B 35/65

(52) U.S. Cl. CPC C04B 35/80; C04B 2235/9669; C04B 35/62894; C04B 35/62897; C04B 35/62892; C04B 35/657; C04B 35/65; C04B 35/62884; C04B 2235/5244; C04B 2235/5252; C04B 2235/386; C04B 2235/3873; C04B 2235/3826; C04B 2235/616; C04B 2235/614; C04B 2235/767; C04B 35/62868

(57) ABSTRACT

A method of making a ceramic matrix composite that exhibits moisture and environmental resistance has been developed. The method includes depositing a diffusion barrier layer comprising boron nitride on silicon carbide fibers and depositing a moisture-tolerant layer comprising silicon-doped boron nitride on the diffusion barrier layer, where a thickness of the moisture-tolerant layer is from about 3 to about 300 times a thickness of the diffusion barrier layer. Thus, a compliant multilayer including the moisture-tolerant layer and the diffusion barrier layer is formed. A wetting layer comprising silicon carbide, boron carbide, and/or pyrolytic carbon is deposited on the compliant multilayer layer. After depositing the wetting layer, a fiber preform comprising the silicon carbide fibers is infiltrated with a slurry. After slurry infiltration, the fiber preform is infiltrated with a melt comprising silicon and then the melt is cooled, thereby forming a ceramic matrix composite.

### TECHNICAL FIELD

The present disclosure relates generally to the fabrication of ceramic matrix composites (CMCs) and more particularly to fabricating a CMC with good moisture and environmental resistance as well as favorable mechanical properties.

### BACKGROUND

Ceramic matrix composites, which include ceramic fibers embedded in a ceramic matrix, exhibit a combination of properties that make them promising candidates for industrial applications, such as gas turbine engines, that demand excellent thermal and mechanical properties along with low weight. A ceramic matrix composite that includes a silicon carbide matrix reinforced with silicon carbide fibers may be referred to as a silicon carbide/silicon carbide composite or SiC/SiC composite. Fabrication of a SiC/SiC composite may include slurry and melt infiltration steps to densify a silicon carbide fiber preform. Prior to the infiltration steps, the fibers making up the silicon carbide preform may be coated with one or more materials to protect the fibers and/or improve the performance of the final densified composite.

### BRIEF DESCRIPTION OF THE DRAWINGS

The embodiments may be better understood with reference to the following drawing(s) and description. The components in the figures are not necessarily to scale. Moreover, in the figures, like-referenced numerals designate corresponding parts throughout the different views.

FIG. 1 is a high resolution transmission electron microscopy (TEM) image providing a cross-sectional view of a portion of a silicon carbide fiber coated with functional layers; scale bar is 500 nm.

FIG. 2. is an electron energy loss spectroscopy (EELS) line scan showing element (e.g., B, C, N, Si) profiles, where at. % of the element is plotted versus depth or distance in nanometers.

FIG. 3 is a flow chart showing exemplary steps of the method.

FIG. 4 is a data plot showing results from moisture exposure testing of fiber preform specimens coated with SiBN at different doping levels.

### DETAILED DESCRIPTION

A method of making a ceramic matrix composite (CMC) that may exhibit improved moisture and environmental resistance without a loss in material performance is described. The method includes controllably depositing a sequence of coatings or layers, each having a particular function, on silicon carbide fibers that serve as reinforcements in the final CMC. In particular, a moisture-tolerant layer is deposited on a diffusion barrier layer to form a compliant multilayer that protects the underlying silicon carbide fibers from environmental degradation in use. After the layers are applied, a fiber preform comprising the silicon carbide fibers may undergo slurry infiltration and then melt infiltration to form the final CMC.

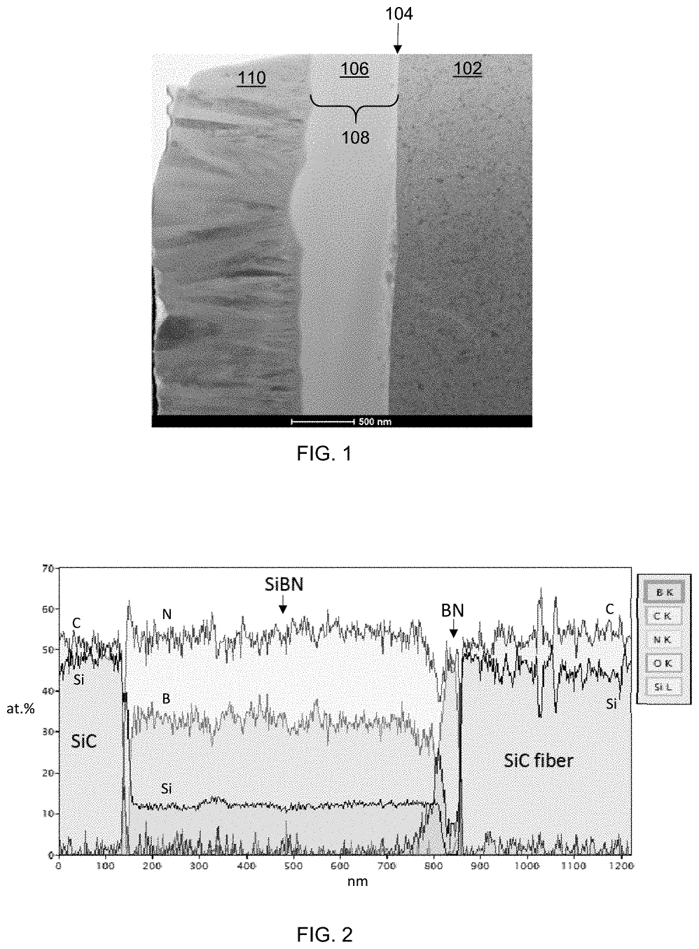

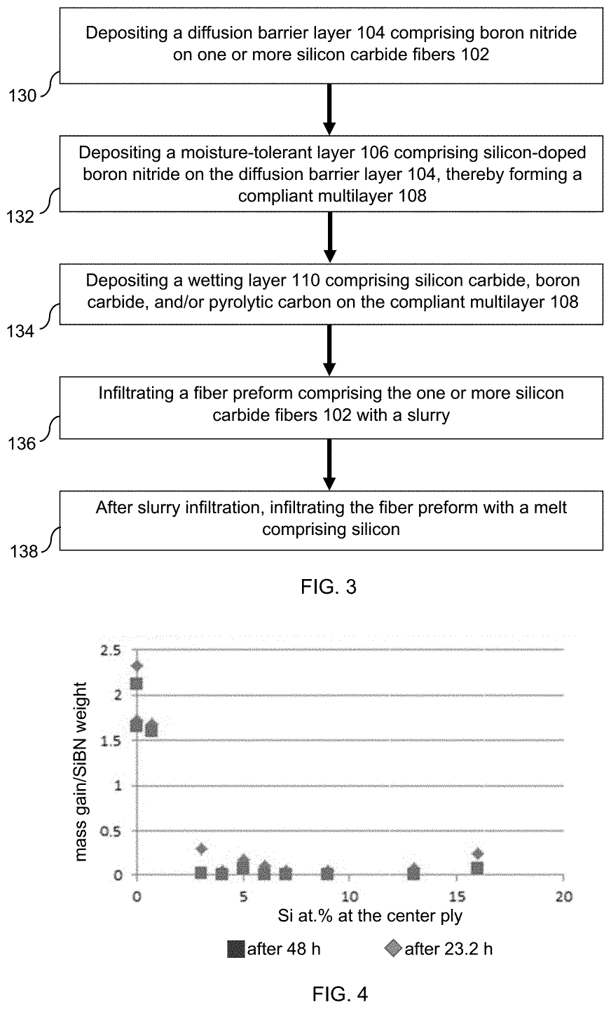

FIG. 1 is a high resolution transmission electron microscopy (TEM) image showing a cross-section of an exemplary silicon carbide fiber that includes a sequence of functional layers or coatings, and FIG. 3 provides a flow chart of the method. Referring to FIGS. 1 and 3, the method entails depositing 130 a diffusion barrier layer 104 comprising boron nitride on one or more silicon carbide fibers 102, which may be referred to as “the silicon carbide fibers.” The diffusion barrier layer 104 may help to ensure a weak fiber-matrix interface in the finished CMC and promote matrix crack deflection, thereby improving fracture toughness. Next, a moisture-tolerant layer 106 comprising silicon-doped boron nitride is deposited 132 on the diffusion barrier layer 104, thereby forming a compliant multilayer 108 that includes the moisture-tolerant and diffusion barrier layers 106,104. The diffusion barrier layer may prevent the silicon carbide fibers 102 and the moisture-tolerant layer 106 from interdiffusing and forming a strong bond, whether during subsequent thermal processing or in use. The diffusion barrier layer 104 may be nanoscale in thickness, and typically the thickness is not greater than about 100 nm; at higher thicknesses, the diffusion barrier layer 104 may show the moisture instability that is sometimes observed with thicker boron nitride coatings in silicon carbide/silicon carbide composites. The moisture-tolerant layer 106 may have a thickness from about 3 to about 300 times the thickness of the diffusion barrier layer 104. A wetting layer 110 comprising silicon carbide, boron carbide (e.g., BₓC, where 0≤x≤4), and/or pyrolytic carbon is deposited 134 on the compliant multilayer layer 108. In some examples, prior to depositing the wetting layer 110, a barrier layer designed to resist wetting by molten silicon may be deposited on the moisture-tolerant layer 106, as discussed further below. After depositing the wetting layer 110, a fiber preform comprising the silicon carbide fibers 102 is infiltrated 136 with a slurry that may include ceramic (e.g., silicon carbide) particles in a carrier fluid. Following slurry infiltration, the fiber preform is infiltrated 138 with a melt comprising silicon, and upon cooling of the melt, a dense CMC which includes the silicon carbide fibers in a ceramic matrix comprising silicon carbide may be formed.

The addition of the moisture-tolerant layer 106 comprising silicon-doped boron nitride may not only enhance the environmental resistance of the CMC in use, but also may help to protect the underlying diffusion barrier layer 104 and silicon carbide fibers 102 from silicon attack during melt infiltration. As indicated above, the thickness of the moisture-tolerant layer 106 is from 3 to 300 times greater than that of the diffusion barrier layer 104, and the thickness may also be from 5 to 100 times that of the diffusion barrier layer 104. For example, the thickness of the moisture-tolerant layer 106 may lie in a range from about 0.4 to about 3 microns, or from about 1.5 microns to about 3 microns, while the thickness of the diffusion barrier layer 104 may lie in a range from about 0.01 micron to about 0.10 micron, or from about 0.05 micron to about 0.10 micron. Diffusion barrier layers having a thickness at the higher end of the range (e.g., about 0.05 micron (50 nm) or higher) may be associated with increased fracture toughness and failure strain. The concentration of silicon in the silicon-doped boron nitride may lie in a range from about 2 at. % to about 30 at. %.

Each of the layers deposited on the silicon carbide fibers 102, which may be referred to as “functional layers,” is described below in order of deposition. It is noted that deposition of the functional layers on the silicon carbide fibers 102 may be carried out using chemical vapor infiltration (CVI) methods. Generally speaking, CVI entails flowing gaseous reagents at an elevated temperature through a furnace or reaction chamber containing one or more porous specimens to be coated. The one or more porous specimens may comprise any arrangement of the silicon carbide fibers 102 (e.g., a fiber preform and/or fiber tows, as discussed below), where interstices between adjacent silicon carbide fibers 102 may be understood to constitute pores. During CVI, the gaseous reagents may infiltrate the porous specimen(s) (e.g., the fiber preform and/or the fiber tows) and chemically react to form a deposit, coating or layer on exposed surfaces of the silicon carbide fibers 102. The porous specimen(s) may be untooled or constrained with a tool during deposition. A suitable tool may include through-holes for passage of the gaseous reagents and may be formed of a chemically inert and/or refractory material, such as graphite or silicon carbide, which is stable at the elevated temperatures at which deposition takes place. Through-holes in the tool may have a diameter or width sized to allow for a sufficient flow of gaseous reactants into the porous specimen during CVI. The tool may have a single-piece or multi-piece construction suitable for constraining the porous specimen(s) in a desired configuration and for easy removal after deposition of the coatings.

To deposit the diffusion barrier layer 104 comprising boron nitride, the silicon carbide fibers 102 may be exposed to a gaseous atmosphere comprising a flow of nitrogen-containing gas, such as ammonia, and a flow of boron-containing gas, such as boron trichloride, at a temperature in a range from about 700° C. to about 875° C. The gaseous atmosphere may further comprise a flow of a substantially inert carrier gas such as N₂ or H₂. In one example, the diffusion barrier layer 104 may comprise a crystalline (hexagonal) phase of the boron nitride, which is preferred since amorphous or turbostratic boron nitride is more likely to degrade upon exposure to moisture and/or oxygen at elevated temperatures. Crystallinity of the boron nitride may be promoted or ensured by exposure to atmospheric humidity and a heat treatment as described below, which may optionally take place during CVI of a successive layer. Deposition of the diffusion barrier layer 104 may take place over a time duration of 1-10 hours.

In a next step, to enhance moisture and environmental resistance, the moisture-tolerant layer 106 comprising silicon-doped boron nitride is deposited on the diffusion barrier layer 104. This may entail incorporating a silicon-containing gas into the gaseous atmosphere used to form the underlying diffusion barrier layer 104 which may include flows of the nitrogen-containing gas and the boron-containing gas as described above along with a substantially inert carrier gas such as N₂ or H₂. Notably, it has been found that using H₂ as a carrier gas instead of N₂ may lead to a 50% increase in deposition rate of the silicon-doped boron nitride, and thus H₂ is preferred. A suitable silicon-containing gas may include methyltrichlorosilane (CH₃SiCl₃), trichlorosilane (HSiCl₃), dichlorosilane (H₂SiCl₂), silicon tetrachloride (SiCl₄), and/or silane (SiH₄). Typically, CVI of silicon-doped boron nitride is carried out at a temperature in a range from about 700° C. to about 875° C. Deposition of the moisture-tolerant layer 106 may take place over a time duration of 10-70 hours.

In addition to serving as a compliant release layer, the diffusion barrier layer 104 may function as a diffusion barrier between carbon enrichment/non-stoichiometry of the silicon carbide fiber and/or residual carbon (sizing) char on the silicon carbide fibers 102 and the moisture-tolerant layer 106. To promote crystallinity of the diffusion barrier layer 104 (e.g., formation of the hexagonal boron nitride phase) as mentioned above, the method may further include exposing the diffusion barrier layer 104 and/or the compliant multilayer 108 to atmospheric humidity, and then heat treating the diffusion barrier layer 104 and/or the compliant multilayer 108 at a temperature in a range from about 900° C. to about 1150° C., preferably in an inert atmosphere.

As described above, an optional barrier layer having a high contact angle with molten silicon may be deposited on the compliant multilayer 108 prior to deposition of the wetting layer 110. For the barrier layer to serve as an effective chemical barrier, it is preferred that the contact angle is at least about 45°. Accordingly, the barrier layer may comprise silicon nitride or silicon nitrocarbide, such as SiₓN_{y}C_{z}, which both may exhibit the requisite contact angle with molten silicon. In one example, 0.1<x<0.697, 0.3<y<0.6, and 0.003<z<0.33; that is, the barrier layer may include carbon at a concentration from about 0.3 at. % to 33 at. % and nitrogen at a concentration from about 30 at. % to 60 at. %, with a balance of silicon and any incidental impurities. Silicon nitrocarbide may be understood to comprise a mixture of silicon carbide (SiC), silicon nitride (Si₃N₄), and/or carbon (C). The silicon nitrocarbide may be amorphous and may remain amorphous during CVI processing due at least in part to the presence of carbon, which may inhibit or prevent crystallization. Consequently, crystallization-induced shrinkage cracking of the barrier layer, a problem that can be associated with amorphous silicon nitride, which does not include any appreciable amount of carbon, may be beneficially avoided. If the barrier layer comprises silicon nitride (e.g., Si₃N₄), crystalline silicon nitride is preferred, and more particularly crystalline silicon nitride which is devoid of cracks. The barrier layer may be deposited to have a thickness in a range from about 0.005 micron to about 2 micron, or more preferably in a range from about 0.3 micron to about 1 micron.

The positioning of the barrier layer between the compliant multilayer 108 and the wetting layer 110 may lead to improvements in the fabrication and properties of the CMC. Previous work has shown that molten silicon can diffuse through a silicon carbide wetting or rigidization layer and chemically attack the underlying diffusion barrier layer and/or the silicon carbide fibers. Here, the barrier layer may be deposited prior to the rigidization or wetting layer 110 and thus may be uniquely positioned to provide a chemical barrier against silicon attack without sacrificing the wettability desired for the wetting layer 110.

Deposition of the barrier layer on the compliant multilayer 108 may comprise exposing the compliant multilayer 108 to a gaseous atmosphere comprising a flow of a silicon-containing gas and a flow of a nitrogen-containing gas, which may entail halting the flow of the boron-containing gas into the gaseous atmosphere while the nitrogen- and/or silicon-containing gases continue to flow as described above, at a temperature in a range from about 700° C. to about 1000° C. It may be beneficial to halt the flow of the boron-containing gas for 5-30 minutes before the flows of the nitrogen- and silicon-containing gases are halted. If the intent is to deposit a barrier layer comprising silicon nitrocarbide, instead of silicon nitride, then a flow of a carbon-containing gas may be included in the gaseous atmosphere. The carbon-containing gas may be the same as or different from the silicon-containing gas or the nitrogen-containing gas. In other words, the silicon-containing gas or the nitrogen-containing gas may also include carbon. One example of a silicon-containing gas that includes carbon is methyltrichlorosilane (CH₃SiCl₃), as mentioned above, which is also known as MTS. In addition to the silicon-, nitrogen- and/or carbon-containing gases, which may individually or collectively be referred to as reactive gas(es), the gaseous atmosphere may further include a flow of a carrier gas, which as indicated above may be a nonreactive or reactive gas and which may be selected from N₂ and H₂.

After deposition of the optional barrier layer, the wetting layer 110, which may in some cases function also as a rigidization layer, may be deposited. Typically, the wetting layer 110 comprises silicon carbide, boron carbide, and/or pyrolytic carbon. Deposition may entail CVI utilizing a flow of a silicon-containing gas or a boron-containing gas that further contains carbon, such as, in one example, the MTS mentioned above. Prior to CVI of the wetting layer 110, the flow of all gases except the carrier gas (e.g., H₂ or N₂) may be halted and the furnace may be cooled. Typically, the wetting layer 110 has a thickness in a range from about 0.5 micron to about 10 microns. CVI of the wetting layer 110 may be carried out from about 1 hour to about 60 hours, and generally at a temperature in a range from about 600° C. to about 1500° C.

The silicon carbide fibers 102 that undergo coating may be arranged in a fiber tow, unidimensional tape, braid, ply, and/or woven fabric (e.g., 2D woven, 3D woven and/or 2.5D woven), and may further be part of a fiber preform that has a predetermined shape, such as an airfoil shape. The fiber preform is typically produced in a lay-up process from the plies, woven fabrics and/or tapes and may be described as a three-dimensional framework of the silicon carbide fibers or fiber tows. Typically, the silicon carbide fibers 102 are assembled into a fiber preform prior to CVI.

After deposition of the functional layers, the silicon carbide fibers may be referred to as coated silicon carbide fibers, and the fiber preform may be referred to as a rigidized preform. Deposition of the functional layers may be followed by slurry infiltration to impregnate the rigidized preform with matrix precursors, forming what may be referred to as an impregnated fiber preform. A suitable slurry may include ceramic particles (e.g., particulate silicon carbide) and/or particulate reactive elements (e.g., elements reactive with molten silicon or a molten silicon alloy), such as carbon, in an aqueous or organic liquid. The slurry may further include a carbonaceous resin, such as phenolic or furfuryl alcohol. In some cases, the carbonaceous resin may be separately infiltrated into the rigidized preform after slurry infiltration, or may not be used at all. If a carbonaceous resin is employed, one or more additional steps, such as curing and/or pyrolysis, may be carried out to convert the resin to carbon. Typically, the impregnated fiber preform comprises a loading level of particulate matter, including ceramic particles and particulate reactive elements, from about 40 vol. % to about 60 vol. %, with the remainder being porosity. The method may further comprise infiltrating the fiber preform with molten material (e.g., molten silicon or a molten silicon alloy) followed by cooling to form a densified ceramic matrix composite. Due to the presence of the barrier coating, the silicon carbide fibers and the diffusion barrier layer (or compliant multilayer) may be protected from attack by molten silicon.

During melt infiltration, the molten material infiltrated into the rigidized and/or impregnated fiber preform may consist essentially of silicon (e.g., elemental silicon and any incidental impurities) or may comprise a silicon-rich alloy. Melt infiltration may be carried out at a temperature at or above the melting temperature of silicon or the silicon alloy which is infiltrated. Thus, the temperature for melt infiltration is typically in a range from about 1380° C. to about 1700° C. In one example, a ramp rate from an intermediate temperature of about 800° C. to a temperature above about 1380° C. may be less than about 10° C./min. A suitable time duration for melt infiltration may be from 15 minutes to four hours, depending in part on the size and complexity of the ceramic matrix composite to be formed. A ceramic matrix is formed from ceramic particles as well as ceramic reaction products created from reactions between the molten material and any other particles (e.g., carbon particles, refractory metal particles) in the fiber preform. Preferably, the final ceramic matrix composite is substantially devoid of closed porosity. In some cases, the ceramic matrix composite may form part or all of a gas turbine engine component, such as a blade or vane.

### Example

5HS Hi-Nicalon Type S fabric is preformed into a 6.5″×7″×0.200″ panel, tooled into a graphite tool with diffusion holes, and loaded in a furnace. After evacuation, the furnace is heated to 1000° C. for 5 mins to 1 hour for heat treatment of the panel/fiber preform. The furnace temperature is then cooled to 750 to 850° C. and flows of N₂, BCl₃, and NH₃ are introduced for three hours to apply a diffusion barrier layer comprising boron nitride on the silicon carbide fibers of the preform. Next, a flow of MTS is added to the gaseous atmosphere for 25 to 40 hours, and a moisture tolerant layer comprising silicon-doped boron nitride is deposited on the diffusion barrier layer, forming a compliant multilayer. In a next step, the BCl₃ is shut off for 15 minutes while the flows of MTS, NH₃ and N₂ continue to form a silicon nitrocarbide barrier layer. Finally, the flow of all gases except N₂ are halted and the furnace is cooled. Subsequently, a SiC layer is deposited to form a rigidization or wetting layer. The preform may be slurry infiltrated with a SiC-containing slurry followed by melt infiltration with silicon or a silicon alloy to form a SiC/SiC composite.

The microstructure of the functional coatings on the silicon carbide fiber is shown by the transmission electron microscopy (TEM) image of FIG. 1 in conjunction with an electron energy loss spectroscopy (EELS) line scan that provides elemental profiles, as shown in FIG. 2. The data reveal that the exemplary sample includes a moisture-tolerant layer comprising silicon-doped boron nitride (“SiBN”) containing about 11-12 at. % silicon. The thickness of the SiBN layer is approximately 0.65 micron (650 nm), and the thickness of the diffusion barrier layer comprising BN is approximately 0.05 micron (50 nm).

FIG. 4 shows a data plot of moisture exposure test results from fiber preform specimens coated with SiBN at different doping levels. The moisture testing was conducted at 65° C. and 95% relative humidity. As indicated in the plot, weight gain from hydrolysis significantly decreases with the silicon dopant level is greater than about 3 at. %.

To clarify the use of and to hereby provide notice to the public, the phrases “at least one of <A>, <B>, . . . and <N>” or “at least one of <A>, <B>, <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

While various embodiments have been described, it will be apparent to those of ordinary skill in the art that many more embodiments and implementations are possible. Accordingly, the embodiments described herein are examples, not the only possible embodiments and implementations.

The subject-matter of the disclosure may also relate, among others, to the following aspects:

A first aspect relates to a method of making a ceramic matrix composite that exhibits moisture and environmental resistance. The method comprises: depositing a diffusion barrier layer comprising boron nitride on silicon carbide fibers; depositing a moisture-tolerant layer comprising silicon-doped boron nitride on the diffusion barrier layer, a thickness of the moisture-tolerant layer being from about 3 to about 300 times a thickness of the diffusion barrier layer, thereby forming a compliant multilayer including the moisture-tolerant layer and the diffusion barrier layer; depositing a wetting layer comprising silicon carbide, boron carbide, and/or pyrolytic carbon on the compliant multilayer layer; after depositing the wetting layer, infiltrating a fiber preform comprising the silicon carbide fibers with a slurry; and after infiltration with the slurry, infiltrating the fiber preform with a melt comprising silicon and then cooling the melt, thereby forming a ceramic matrix composite.

A second aspect relates to the method of the first aspect, wherein the thickness of the moisture-tolerant layer is from about 10 to 100 times the thickness of the diffusion barrier layer.

A third aspect relates to the method of the first or second aspect, wherein the thickness of the diffusion barrier layer is in a range from about 0.01 micron to about 0.10 micron.

A fourth aspect relates to the method of any preceding aspect, wherein the thickness of the moisture-tolerant layer is in a range from about 0.4 micron to about 3 microns.

A fifth aspect relates to the method of any preceding aspect, wherein the moisture-tolerant layer includes silicon at a concentration from about 2 at. % to about 30 at. %.

A sixth aspect relates to the method of any preceding aspect, wherein the diffusion barrier layer comprises a crystalline phase of the boron nitride.

A seventh aspect relates to the method of the sixth aspect, wherein the crystalline phase comprises a hexagonal phase.

An eighth aspect relates to the method of the sixth or seventh aspect, further comprising: exposing the compliant multilayer to atmospheric humidity; and heat treating the compliant multilayer at a temperature in a range from about 900° C. to about 1150° C., thereby forming the crystalline phase.

A ninth aspect relates to the method of any preceding aspect, wherein depositing the diffusion barrier layer comprises exposing the silicon carbide fibers to a gaseous atmosphere comprising: a flow of a carrier gas selected from N₂ and H₂, a flow of a nitrogen-containing gas, and a flow of a boron-containing gas at a temperature in a range from about 700° C. to about 875° C.

A tenth aspect relates to the method of the ninth aspect, wherein the carrier gas comprises H₂.

An eleventh aspect relates to the method of the ninth or tenth aspect, wherein the nitrogen-containing gas comprises ammonia.

A twelfth aspect relates to the method of any of the ninth through the eleventh aspects, wherein the boron-containing gas comprises boron trichloride.

A thirteenth aspect relates to the method of any of the ninth through the twelfth aspects, further comprising, after depositing the diffusion barrier layer, introducing a flow of silicon-containing gas into the gaseous atmosphere to deposit the moisture-tolerant layer on the diffusion barrier layer.

A fourteenth aspect relates to the method of the thirteenth aspect, wherein the silicon-containing gas is selected from the group consisting of methyltrichlorosilane (CH₃SiCl₃), trichlorosilane (HSiCl₃), dichlorosilane (H₂SiCl₂), silicon tetrachloride (SiCl₄), and silane (SiH₄).

A fifteenth aspect relates to the method of any preceding aspect, wherein the diffusion barrier layer is deposited over a time duration from about one hour to about 10 hours.

A sixteenth aspect relates to the method of any preceding aspect, wherein the moisture-containing layer is deposited over a time duration from about 10 to about 70 hours.

A seventeenth aspect relates to the method of any preceding aspect, further comprising, prior to depositing the wetting layer, depositing a barrier layer having a high contact angle with molten silicon on the compliant multilayer.

An eighteenth aspect relates to the method of the seventeenth aspect, wherein the barrier layer comprises silicon nitrocarbide or silicon nitride.

A nineteenth aspect relates to any preceding aspect, further comprising, prior to coating the plurality of silicon carbide fibers with the diffusion barrier layer, forming the fiber preform comprising the silicon carbide fibers.

A twentieth aspect relates to a fiber preform for fabricating a ceramic matrix composite, the fiber preform comprising: silicon carbide fibers coated with a plurality of functional layers, the functional layers including: a diffusion barrier layer comprising boron nitride deposited on the silicon carbide fibers; a moisture-tolerant layer comprising silicon-doped boron nitride deposited on the diffusion barrier layer, a thickness of the moisture-tolerant layer being from about 3 to about 300 times a thickness of the diffusion barrier layer, the moisture-tolerant layer and the diffusion barrier layer together defining a compliant multilayer; and a wetting layer comprising silicon carbide, boron carbide, and/or pyrolytic carbon deposited on the compliant multilayer layer.

In addition to the features mentioned in each of the independent aspects enumerated above, some examples may show, alone or in combination, the optional features mentioned in the dependent aspects and/or as disclosed in the description above and shown in the figures.

What is claimed is:

1. A method of making a ceramic matrix composite that exhibits moisture and environmental resistance, the method comprising:
depositing a diffusion barrier layer comprising boron nitride on silicon carbide fibers;
depositing a moisture-tolerant layer comprising silicon-doped boron nitride on the diffusion barrier layer, a thickness of the moisture-tolerant layer being from about 3 to about 300 times a thickness of the diffusion barrier layer, thereby forming a compliant multilayer including the moisture-tolerant layer and the diffusion barrier layer;
depositing a wetting layer comprising silicon carbide, boron carbide, and/or pyrolytic carbon on the compliant multilayer layer;
after depositing the wetting layer, infiltrating a fiber preform comprising the silicon carbide fibers with a slurry; and
after infiltration with the slurry, infiltrating the fiber preform with a melt comprising silicon and then cooling the melt, thereby forming a ceramic matrix composite.

2. The method of claim 1, wherein the thickness of the moisture-tolerant layer is from about 10 to 100 times the thickness of the diffusion barrier layer.

3. The method of claim 1, wherein the thickness of the diffusion barrier layer is in a range from about 0.01 micron to about 0.10 micron.

4. The method of claim 1, wherein the thickness of the moisture-tolerant layer is in a range from about 0.4 micron to about 3 microns.

5. The method of claim 1, wherein the moisture-tolerant layer includes silicon at a concentration from about 2 at. % to about 30 at. %.

6. The method of claim 1, wherein the diffusion barrier layer comprises a crystalline phase of the boron nitride.

7. The method of claim 6, wherein the crystalline phase comprises a hexagonal phase.

8. The method of claim 6, further comprising:
exposing the compliant multilayer to atmospheric humidity; and
heat treating the compliant multilayer at a temperature in a range from about 900° C. to about 1150° C., thereby forming the crystalline phase.

9. The method of claim 1, wherein depositing the diffusion barrier layer comprises exposing the silicon carbide fibers to a gaseous atmosphere comprising:
a flow of a carrier gas selected from N₂ and H₂,
a flow of a nitrogen-containing gas, and
a flow of a boron-containing gas at a temperature in a range from about 700° C. to about 875° C.

10. The method of claim 9, wherein the carrier gas comprises H₂.

11. The method of claim 9, wherein the nitrogen-containing gas comprises ammonia.

12. The method of claim 9, wherein the boron-containing gas comprises boron trichloride.

13. The method of claim 9, further comprising, after depositing the diffusion barrier layer, introducing a flow of silicon-containing gas into the gaseous atmosphere to deposit the moisture-tolerant layer on the diffusion barrier layer.

14. The method of claim 13, wherein the silicon-containing gas is selected from the group consisting of methyltrichlorosilane (CH₃SiCl₃), trichlorosilane (HSiCl₃), dichlorosilane (H₂SiCl₂), silicon tetrachloride (SiCl₄), and silane (SiH₄).

15. The method of claim 1, wherein the diffusion barrier layer is deposited over a time duration from about one hour to about 10 hours.

16. The method of claim 1, wherein the moisture-containing layer is deposited over a time duration from about 10 hours to about 70 hours.

17. The method of claim 1, further comprising, prior to depositing the wetting layer, depositing a barrier layer having a high contact angle with molten silicon on the compliant multilayer.

18. The method of claim 17, wherein the barrier layer comprises silicon nitrocarbide or silicon nitride.

19. The method of claim 1, further comprising, prior to coating the silicon carbide fibers with the diffusion barrier layer, forming the fiber preform comprising the silicon carbide fibers.

20. A fiber preform for fabricating a ceramic matrix composite, the fiber preform comprising:
silicon carbide fibers coated with a plurality of functional layers, the functional layers including:
a diffusion barrier layer comprising boron nitride deposited on the silicon carbide fibers;
a moisture-tolerant layer comprising silicon-doped boron nitride deposited on the diffusion barrier layer, a thickness of the moisture-tolerant layer being from about 3 to about 300 times a thickness of the diffusion barrier layer, the moisture-tolerant layer and the diffusion barrier layer together defining a compliant multilayer; and
a wetting layer comprising silicon carbide, boron carbide, and/or pyrolytic carbon deposited on the compliant multilayer layer.
